(19) United States
(12) Patent Application Publication
(10) Pub. No.: US 2018/0012853 A1
(43) Pub. Date: Jan. 11, 2018

(54) CHIP PACKAGE AND MANUFACTURING METHOD THEREOF

(71) Applicant: XINTEC INC., Taoyuan City (TW)

(72) Inventors: Hsi-Chien LIN, Zhubei City (TW); Jyh-Wei CHEN, New Taipei City (TW); Jun-Chi HSIEH, Hsinchu City (TW); Yue-Ting CHEN, Changhua City (TW)

(21) Appl. No.: 15/643,012

(22) Filed: Jul. 6, 2017

Related U.S. Application Data
(60) Provisional application No. 62/360,018, filed on Jul. 8, 2016.

(51) Int. Cl. H01L 23/00; H01L 23/31; H01L 21/56; G06K 9/00

(52) U.S. Cl. CPC H01L 24/02; H01L 24/82; H01L 21/56; H01L 23/3142; H01L 23/3171; H01L 24/08; G06K 9/00013; H01L 2224/02333; H01L 2224/0235; H01L 2224/0236; H01L 2224/02373; H01L 2224/08221

(57) ABSTRACT

A chip package includes a chip, an isolation layer on the bottom surface and the sidewall, a redistribution layer that is on the isolation layer and in electrical contact with a side surface of the conductive pad, and a passivation layer. The chip has a sensor, at least one conductive pad, a top surface, a bottom surface, and a sidewall. The sensor is located on the top surface. The conductive pad is located on an edge of the top surface. The redistribution layer at least partially protrudes from the conductive pad so as to be exposed. The passivation layer is located on the isolation layer and the redistribution layer, such that the redistribution layer not protruding from the conductive pad is between the passivation layer and the isolation layer, and the redistribution layer protruding from the conductive pad is located on the passivation layer.

### RELATED APPLICATIONS

This application claims priority to U.S. provisional Application Ser. No. 62/360,018, filed Jul. 8, 2016, which is herein incorporated by reference.

### BACKGROUND

### Field of Invention

The present invention relates to a chip package and a manufacturing method of the chip package.

### Description of Related Art

Generally speaking, a chip package used for image sensing or fingerprint sensing may include a chip, a dam element, a redistribution layer (RDL), and a ball grid array (BGA). The redistribution layer may extend to a side surface of the chip from a bottom surface of the chip, such that the redistribution layer on the bottom surface of the chip may be utilized to electrically connect a solder ball of the ball grid array, and the redistribution layer on the side surface of the chip may be utilized to electrically connect the a conductive pad of the chip. As a result, an external electronic device may be electrically connected to an inner line and a sensor of the chip through the solder ball, the redistribution layer, and the conductive pad.

In manufacturing the chip package, the dam element has to cover the top surface and the conductive pad of a wafer which is not yet divided to form plural chips, such that the dam element and the bottom surface of the wafer may form a recess to expose a side surface of the conductive pad. Due to process limitations, in order to prevent the dam element from being penetrated when the recess is formed, the thickness of the dam element is required to be greater than 40 μm. Thereafter, the redistribution layer may be formed on the bottom surface of the wafer, a surface of the wafer facing the recess, the side surface of the conductive pad, and the dam element in the recess. However, after a subsequent dicing process, because the top surface of the chip on which the sensor is disposed and is covered by the dam element, the sensing capability of the chip package is degraded.

### SUMMARY

An aspect of the present invention is to provide a chip package.

According to an embodiment of the present invention, a chip package includes a chip, a first isolation layer, a redistribution layer, and a passivation layer. The chip has a sensor, at least one conductive pad, a top surface, a bottom surface that is opposite the top surface, and a sidewall adjacent to the top surface and the bottom surface. The sensor is located on the top surface, and the conductive pad is located on an edge of the top surface. The first isolation layer is located on the bottom surface and the sidewall of the chip. The redistribution layer is located on the first isolation layer, and is in electrical contact with a side surface of the conductive pad. The redistribution layer at least partially protrudes from the conductive pad so as to be exposed. The passivation layer is located on the first isolation layer and the redistribution layer, such that the redistribution layer not protruding from the conductive pad is located between the passivation layer and the first isolation layer, and the redistribution layer protruding from the conductive pad is located on the passivation layer.

An aspect of the present invention is to provide a manufacturing method of a chip package.

According to an embodiment of the present invention, a manufacturing method of a chip package includes bonding a carrier to a wafer by a temporary bonding layer, in which the wafer has a sensor, at least one conductive pad, a top surface, a bottom surface that is opposite the top surface, and the sensor and the conductive pad are located on the top surface and are covered by the temporary bonding layer, etching the bottom surface of the wafer to form a trench to expose the conductive pad, forming an isolation layer to cover the bottom surface and the trench of the wafer, forming a recess in the isolation layer and the temporary bonding layer that are in the trench, thereby exposing a side surface of the conductive pad through the recess, forming a redistribution layer on the isolation layer, the side surface of the conductive pad, and the temporary bonding layer that is in the recess, in which the redistribution layer at least partially protrudes from the conductive pad, and removing the temporary bonding layer and the carrier to expose the redistribution layer that protrudes from the conductive pad.

In the aforementioned embodiment of the present invention, since the temporary bonding layer is utilized to bond the carrier to the wafer, the recess extends into the temporary bonding layer when the recess exposing the side surface of the conductive pad is formed in the isolation layer that is in the trench. After the redistribution is formed, the temporary bonding layer and the carrier may be removed, and thus the redistribution layer at least partially protrudes from the conductive pad so as to be exposed. As a result, there is no typical dam element dam element covering the chip package on which the sensor is disposed, thereby improving the sensing capability of the chip package.

An aspect of the present invention is to provide a manufacturing method of a chip package.

According to an embodiment of the present invention, a manufacturing method of a chip package includes forming a dam layer on a top surface and a first portion of a conductive pad of a wafer, in which the wafer has a sensor and a bottom surface that is opposite the top surface, and the sensor and the conductive pad are located on the top surface; bonding a carrier to the wafer by a temporary bonding layer, in which the sensor and a second portion of the conductive pad are covered by the temporary bonding layer, and the dam layer is located between the temporary bonding layer and the wafer; etching the bottom surface of the wafer to form a trench to expose the conductive pad; forming an isolation layer to cover the surface and the trench of the wafer; forming a recess in the isolation layer and the dam layer that are in the trench, thereby exposing a side surface of the conductive pad through the recess; forming a redistribution layer on the isolation layer, the side surface of the conductive pad, and the dam layer that is in the recess, in which the redistribution layer at least partially protrudes from the conductive pad; and removing the temporary bonding layer and the carrier to expose the second portion of the conductive pad and the dam layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of a chip package according to one embodiment of the present invention;

FIG. 2 is a cross-sectional view of a chip package according to one embodiment of the present invention;

FIG. 3 is a cross-sectional view of a chip package according to one embodiment of the present invention;

FIG. 4 is a cross-sectional view of a chip package according to one embodiment of the present invention;

FIG. 5 is a flow chart of a manufacturing method of a chip package according to one embodiment of the present invention;

FIG. 6 is a cross-sectional view after a carrier is bonded to a wafer according to one embodiment of the present invention;

FIG. 7 is a cross-sectional view after a trench is formed in the wafer of FIG. 6 and is covered by an isolation layer;

FIG. 8 is a cross-sectional view after a recess is formed in the isolation layer and a temporary bonding layer of FIG. 7;

FIG. 9 is a cross-sectional view after a redistribution layer is formed on the isolation layer, a conductive pad, and the temporary bonding layer of FIG. 8;

FIG. 10 is a cross-sectional view after a passivation layer is formed on the isolation layer and the redistribution layer of FIG. 9 and after a conductive structure is formed on the redistribution layer shown in FIG. 9;

FIG. 11 is a cross-sectional view after a carrier is bonded to a supporting layer on a wafer according to one embodiment of the present invention;

FIG. 12 is a cross-sectional view after a trench is formed in the wafer of FIG. 11, after the trench is covered by an isolation layer, and after a recess is formed in the isolation layer, the supporting layer, and the temporary bonding layer of FIG. 11;

FIG. 13 is a cross-sectional view after a redistribution layer is formed on the isolation layer, a conductive pad, the supporting layer, and the temporary bonding layer of FIG. 12, after a passivation layer is formed on the isolation layer of FIG. 12 and the redistribution layer, and after a conductive structure is formed on the redistribution layer; and

FIGS. 14 to 17 are cross-sectional views showing a manufacturing method of a chip package according to one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

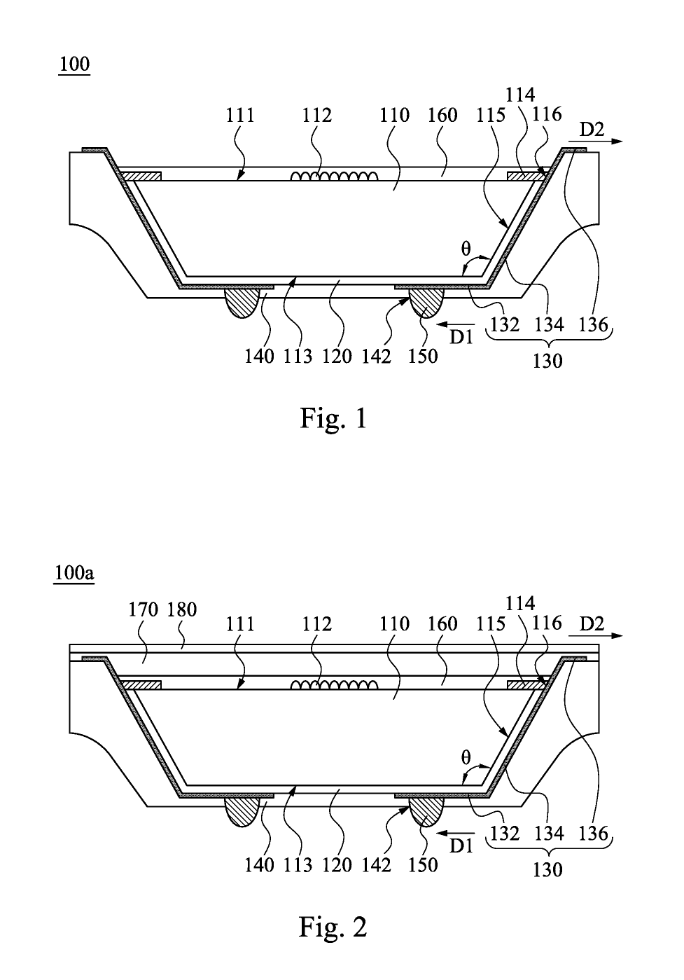

FIG. 1 is a cross-sectional view of a chip package 100 according to one embodiment of the present invention. As shown in FIG. 1, the chip package 100 includes a chip 110, an isolation layer 120, a redistribution layer 130, and a passivation layer 140. The chip 110 has a sensor 112, at least one conductive pad 114, a top surface 111, a bottom surface 113 that is opposite the top surface 111, and a sidewall 115 adjacent to the top surface 111 and the bottom surface 113. The chip 110 may be made of silicon. The sensor may be an image sensor or fingerprint sensor, such as a CMOS image sensor, but the present invention is not limited in this regard. The sensor 112 is located on the top surface 111, and the conductive pad 114 is located on an edge of the top surface 111. The conductive pad 114 may be electrically connected to the sensor 112 through inner lines of the chip 110. The isolation layer 120 is located on the bottom surface 113 and the sidewall 115 of the chip 110.

Moreover, the redistribution layer 130 is located on the isolation layer 120, and is in electrical contact with a side surface 116 of the conductive pad 114. The redistribution layer 130 at least partially protrudes from the conductive pad 114 so as to be exposed. For example, the redistribution layer 130 at the upper right side of the right conductive pad 114 of FIG. 1 protrudes from the conductive pad 114 to be exposed. The passivation layer 140 is located on the isolation layer 120 that is on the bottom surface 113 of the chip 110 and the redistribution layer 130, such that the redistribution layer 130 not protruding from the conductive pad 114 (e.g., the redistribution layer 130 at the lower left side of the right conductive pad 114 of FIG. 1) is located between the passivation layer 140 and the isolation layer 120, and the redistribution layer 130 protruding from the conductive pad 114 is located on the passivation layer 140.

In other words, an orthogonal projection of the redistribution layer 130 that protrudes from the conductive pad 114 on the passivation layer 140 is not overlapped with an orthogonal projection of the chip 110 on the passivation layer 140, and an orthogonal projection of the redistribution layer 130 that protrudes from the conductive pad 114 on the passivation layer 140 is not overlapped with an orthogonal projection of the conductive pad 114 on the passivation layer 140. Since there is no typical dam element dam element covering the chip package 100 on which the sensor 112 is disposed, the sensing capability of the chip package 100 can be improved.

In this embodiment, the redistribution layer 130 has a first segment 132, a second segment 134, and a third segment 136 that are connected in sequence. The first segment 132 is located on the isolation layer 120 that is on the bottom surface 113 of the chip 110. The second segment 134 is located on the isolation layer 120 that is on the sidewall 115 of the chip 110. The third segment 136 protrudes from the conductive pad 114 and is located on a surface of the passivation layer 140 that is adjacent to the conductive pad 114. Furthermore, the first segment 132 and the third segment 136 of the redistribution layer 130 extend in two opposite directions. That is, the first segment 132 extends in a direction D1 and the third segment 136 extends in a direction D2, such that the redistribution layer 130 has a stepped shape. An obtuse angle θ is formed between the sidewall 115 and the bottom surface 113 of the chip 110, and another obtuse angle is also formed between the first segment 132 and the second segment 134 of the redistribution layer 130.

The chip package 100 further includes a conductive structure 150. The passivation layer 140 has at least one opening 142, and the conductive structure 150 is located on the redistribution layer 130 that is in the opening 142. The conductive structure 150 may be disposed on a printed circuit board to enable an external electronic device to electrically connect the sensor 112 through the redistribution layer 130 and the conductive pad 114.

In addition, in this embodiment, the chip package 100 may further include an isolation layer 160. The isolation layer 160 is located on the top surface 111 of the chip 110, and the redistribution layer 130 at least partially protrudes from the isolation layer 160 so as to be exposed. The isolation layer 160 may protect the sensor 112 and the conductive pad 114. For example, the isolation layer 160 may prevent moisture from contacting the sensor 112 and the conductive pad 114.

It is to be noted that the connection relationships of the elements described above will not be described again in the following description, and aspects related to other types of chip packages will be described.

FIG. 2 is a cross-sectional view of a chip package 100a according to one embodiment of the present invention. The chip package 100a includes the chip 110, the isolation layer 120, the redistribution layer 130, and the passivation layer 140. The difference between this embodiment and the embodiment shown in FIG. 1 is that the chip package 100a further includes an adhesive layer 170 and a protection sheet 180. The adhesive layer 170 covers the isolation layer 160 and the redistribution layer 130 that protrudes from the isolation layer 160 (e.g., the third segment 136). The protection sheet 180 is located on the adhesive layer 170. In this embodiment, the adhesive layer 170 may be made of a high-k material. The adhesive layer 170 made of the high-k material will not likely affect the sensing capability of the chip package 100a. If the sensor 112 of the chip package 100a is an image sensor, the protection sheet 180 may be light-permeable and allows light to pass through. For example, the protection sheet 180 may be a glass sheet. If the sensor 112 of the chip package 100a is a fingerprint sensor, the protection sheet 180 may be pressed by users' fingers.

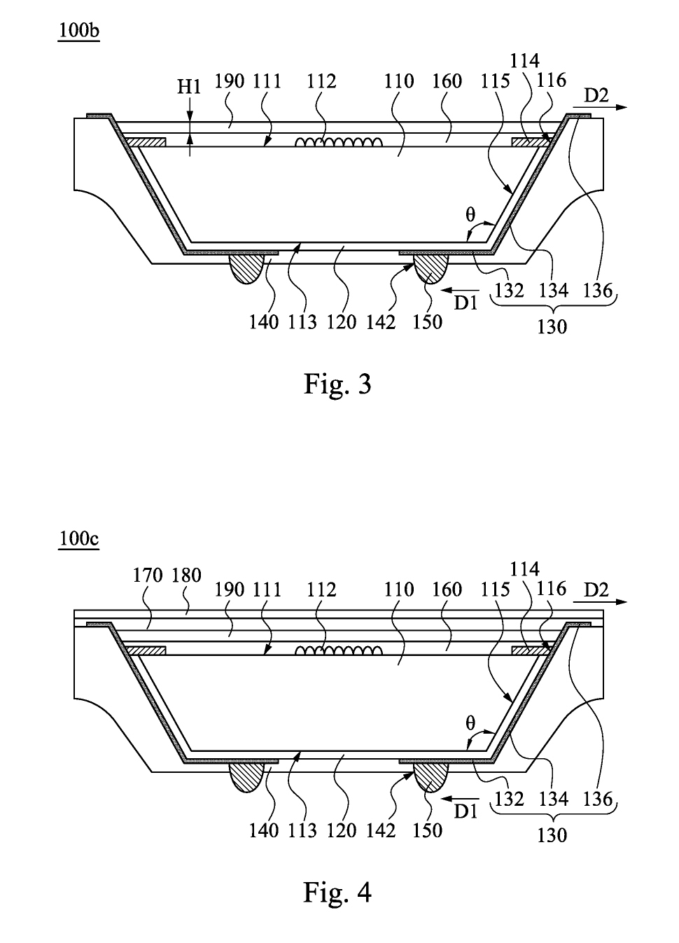

FIG. 3 is a cross-sectional view of a chip package 100b according to one embodiment of the present invention. The chip package 100b includes the chip 110, the isolation layer 120, the redistribution layer 130, and the passivation layer 140. The difference between this embodiment and the embodiment shown in FIG. 1 is that the chip package 100b further includes a supporting layer 190. The supporting layer 190 is located on the isolation layer 160, such that the isolation layer 160 is located between the supporting layer 190 and the chip 110. The redistribution layer 130 at least partially protrudes from the supporting layer 190 so as to be exposed, such as the third segment 136 of the redistribution layer 130. In this embodiment, the thickness H1 of the supporting layer 190 may be in a range from about 5 μm to about 15 μm, such as about 10 μm. The supporting layer 190 may be made of a high-k material, such as barium titanium oxide (BaTiO₃), silicon dioxide (SiO₂), or titanium dioxide (TiO₂). The supporting layer 190 may improve the strength of the chip package 100b, and the supporting layer 190 made of the high-k material does not likely affect the sensing capability of the chip package 100b.

FIG. 4 is a cross-sectional view of a chip package 100c according to one embodiment of the present invention. The chip package 100c includes the chip 110, the isolation layer 120, the redistribution layer 130, the passivation layer 140, and the supporting layer 190. The difference between this embodiment and the embodiment shown in FIG. 3 is that the chip package 100c further includes the adhesive layer 170 and the protection sheet 180. The adhesive layer 170 covers the supporting layer 190 and the redistribution layer 130 that protrudes from the supporting layer 190 (e.g., the third segment 136). The protection sheet 180 is located on the adhesive layer 170. In this embodiment, the adhesive layer 170 may be made of a high-k material. The adhesive layer 170 made of the high-k material does not likely affect the sensing capability of the chip package 100c. If the sensor 112 of the chip package 100c is an image sensor, the protection sheet 180 may be light-permeable to be passed through by light. If the sensor 112 of the chip package 100a is a fingerprint sensor, the protection sheet 180 may be pressed by users' fingers.

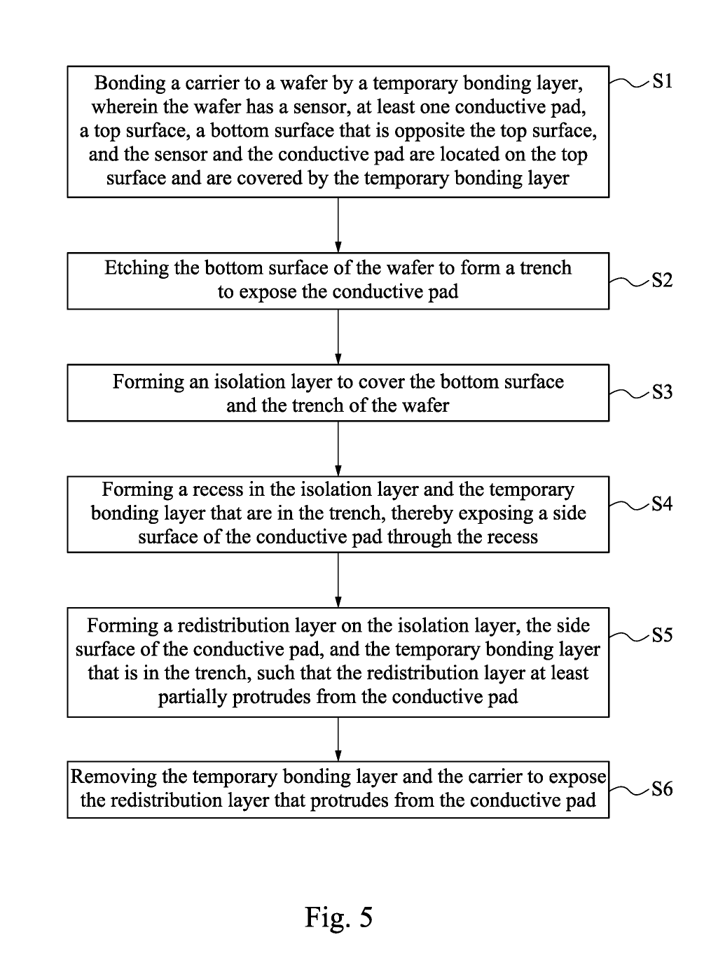

FIG. 5 is a flow chart of a manufacturing method of a chip package according to one embodiment of the present invention. In step S1, a carrier is bonded to a wafer by a temporary bonding layer. The wafer has a sensor, at least one conductive pad, a top surface, a bottom surface that is opposite the top surface. The sensor and the conductive pad are located on the top surface and are covered by the temporary bonding layer. Thereafter, in step S2, the bottom surface of the wafer is etched to form a trench to expose the conductive pad. Next, in step S3, an isolation layer is formed to cover the bottom surface and the trench of the wafer. Thereafter, in step S4, a recess is formed in the isolation layer and the temporary bonding layer that are in the trench, thereby exposing a side surface of the conductive pad through the recess. Next, in step S5, a redistribution layer is formed on the isolation layer, the side surface of the conductive pad, and the temporary bonding layer that is in the recess, such that the redistribution layer at least partially protrudes from the conductive pad. Subsequently, in step S6, the temporary bonding layer and the carrier are removed to expose the redistribution layer that protrudes from the conductive pad. The aforementioned steps will be described hereinafter.

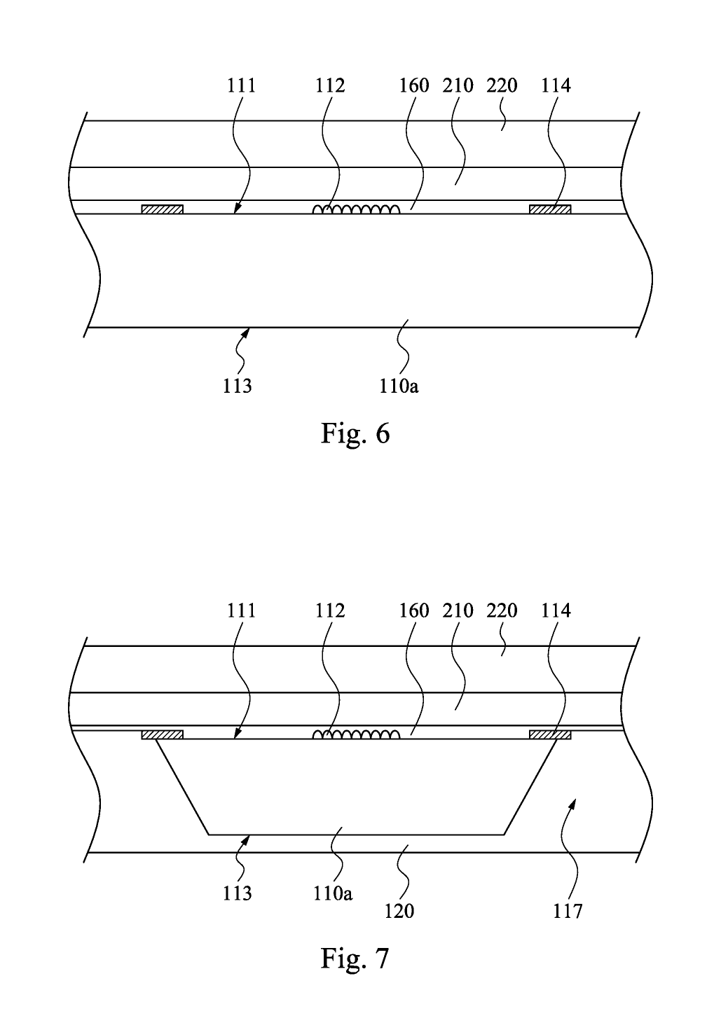

FIG. 6 is a cross-sectional view after a carrier 220 is bonded to a wafer 110a according to one embodiment of the present invention. The wafer 110a is referred to as a semiconductor structure which is not yet divided into plural chips 110 (see FIG. 1), such as a silicon wafer. The carrier 220 may be bonded to the wafer 110a through a temporary bonding layer 210. The wafer 110a has the sensor 112, at least one conductive pad 114, the top surface 111, the bottom surface 113 that is opposite the top surface 111. The sensor 112 and the conductive pad 114 are located on the top surface 111 of the wafer 110a and are covered by the temporary bonding layer 210.

FIG. 7 is a cross-sectional view of after a trench 117 is formed in the wafer 110a of FIG. 6 and covered by the isolation layer 120. As shown in FIG. 6 and FIG. 7, after the carrier 220 is bonded to the wafer 110a, the bottom surface 113 of the wafer 110a may be etched to form the trench 117 to expose the conductive pad 114. Thereafter, the isolation layer 120 may be formed to cover the bottom surface 113 and the trench 117 of the wafer 110a. The position of the wafer on which the trench 117 is located may be utilized as a scribe line for dicing the wafer 110a to form the chip 110 (see FIG. 1) in a subsequent manufacturing process.

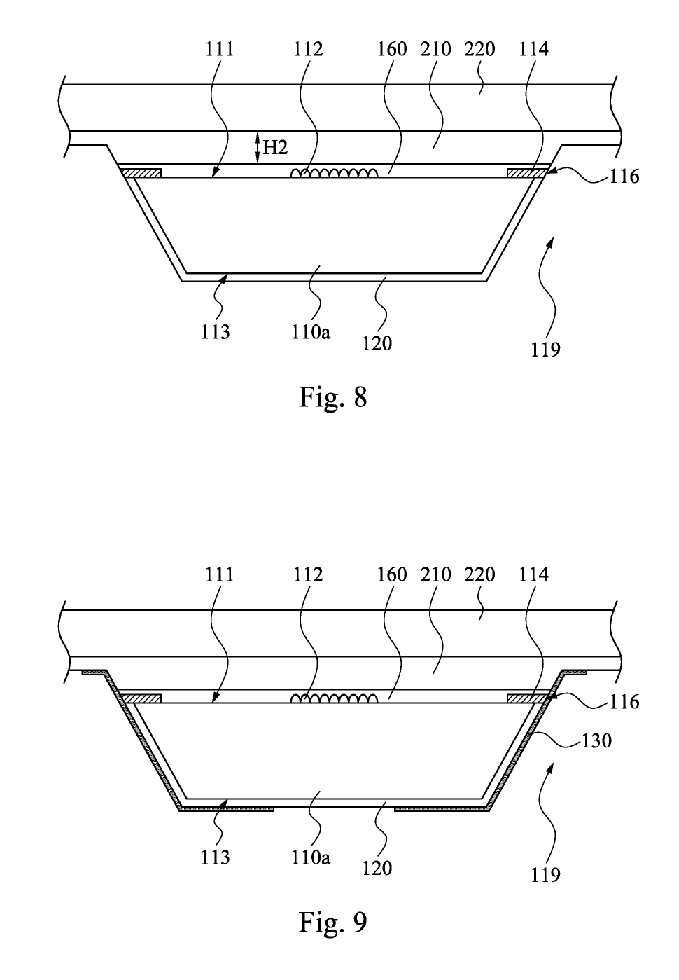

FIG. 8 is a cross-sectional view after a recess 119 is formed in the isolation layer 120 and the temporary bonding layer 210 of FIG. 7. As shown in FIG. 7 and FIG. 8, after the isolation layer 120 covers the bottom surface 113 and the trench 117 of the wafer 110a, the recess 119 may be formed in the isolation layer 120 and the temporary bonding layer 210 that are in the trench 117, thereby exposing the side surface 116 of the conductive pad 114 through the recess 119. Portions of the isolation layer 120 and the temporary bonding layer 210 may be cut off by a cutting tool to form the recess 119. In this embodiment, the thickness H2 of the temporary bonding layer 210 may be in a range from about 50 μm to about 150 μm, such as about 100 μm, to prevent the temporary bonding layer 210 from being penetrated when the recess 119 is formed.

FIG. 9 is a cross-sectional view after the redistribution layer 130 is formed on the isolation layer 120, the conductive pad 114, and the temporary bonding layer 210 of FIG. 8. As shown in FIG. 8 and FIG. 9, after the recess 119 is formed, the redistribution layer 130 may be formed on the isolation layer 120, the side surface 116 of the conductive pad 114, and the temporary bonding layer 210 that is in the recess 119. Since the recess 119 extends into the temporary bonding layer 210, the redistribution layer 130 may at least partially protrudes from the conductive pad 114.

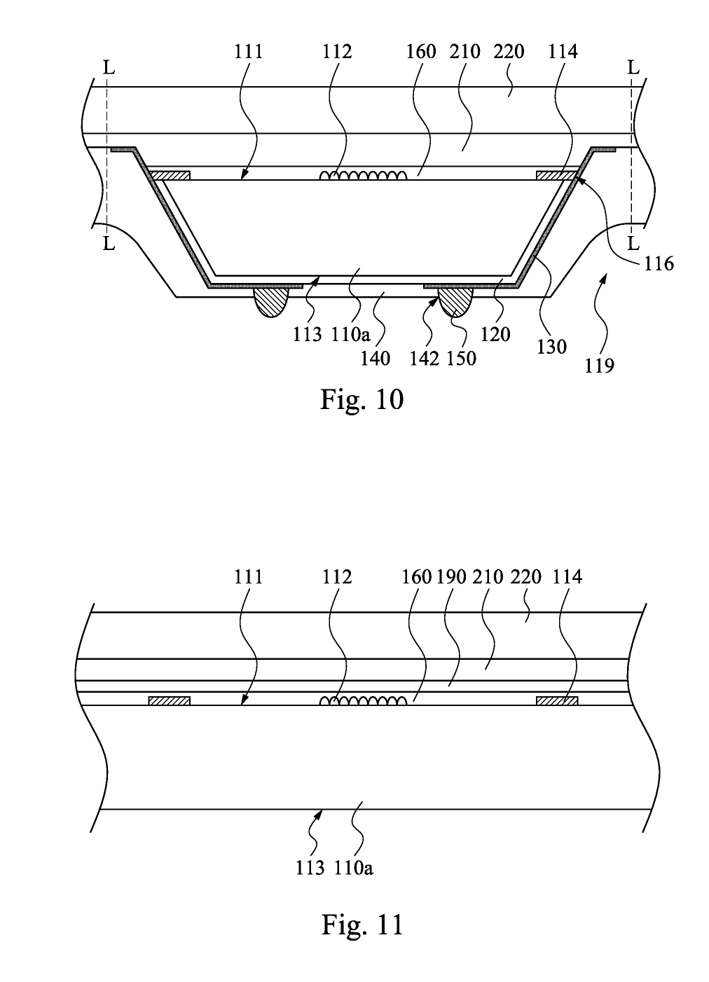

FIG. 10 is a cross-sectional view after the passivation layer 140 is formed on the isolation layer 120 and the redistribution layer 130 of FIG. 9 and after the conductive structure 150 is formed on the redistribution layer 130 of FIG. 9. As shown in FIG. 9 and FIG. 10, after the redistribution layer 130 is formed, the passivation layer 140 may be formed on the isolation layer 120 and the redistribution layer 130, such that the redistribution layer 130 not protruding from the conductive pad 114 is located between the passivation layer 140 and the isolation layer 120, and the redistribution layer 130 protruding from the conductive pad 114 is located on the passivation layer 140. Next, the passivation layer 140 may be patterned to form at least one opening 142, and the redistribution layer 130 is exposed through the opening 142. Thereafter, the conductive structure 150 may be formed on the redistribution layer 130 that is in the opening 142 of the passivation layer 140, such that the conductive structure 150 may be electrically connected to the conductive pad 114 through the redistribution layer 130. After the formation of the conductive structure 150, the passivation layer 140, the temporary bonding layer 210, and the carrier 220 in the recess 119 may be cut along line L-L, and thus the wafer 110a is diced to form more than one chip 110 (see FIG. 1).

After the cutting process, the temporary bonding layer 210 and the carrier 220 may be removed. For example, the adhesion of the temporary bonding layer 210 can be eliminated by ultraviolet. As a result, the redistribution layer 130 protruding from the conductive pad 114 may be exposed at the upper outside of the conductive pad 114, thereby forming the chip package 100 of FIG. 1. As shown in FIG. 1, in the subsequent manufacturing processes, the adhesive layer 170 may be formed to cover the top surface 111 of the chip 110 and the redistribution layer 130 that protrudes from the conductive pad 114, and then the protection sheet 180 is adhered to the adhesive layer 170 to form the chip package 100a of FIG. 2.

In the manufacturing method of the chip package of the present invention, since the temporary bonding layer is utilized to bond the carrier to the wafer, the recess can extend into the temporary bonding layer when the recess exposing the side surface of the conductive pad is formed in the isolation layer that is in the trench. After the redistribution layer is formed, the temporary bonding layer and the carrier may be removed, and thus the redistribution layer at least partially protrudes from the conductive pad so as to be exposed. As a result, there is no typical dam element dam element covering the chip package on which the sensor is disposed, thereby improving the sensing capability of the chip package.

It is to be noted that the aforementioned steps will not be described again hereinafter, and aspects related to manufacturing methods of other types of chip packages will be described.

FIG. 11 is a cross-sectional view after the carrier after 220 is bonded to the supporting layer 190 on the wafer 110a according to one embodiment of the present invention. The difference between this embodiment and the embodiment shown in FIG. 6 is that the supporting layer 190 may be formed on the top surface 111 of the wafer 110a before the carrier 220 is bonded to the wafer 110a by the temporary bonding layer 210, as illustrated in FIG. 11, and thus the carrier 220 is bonded to the supporting layer 190.

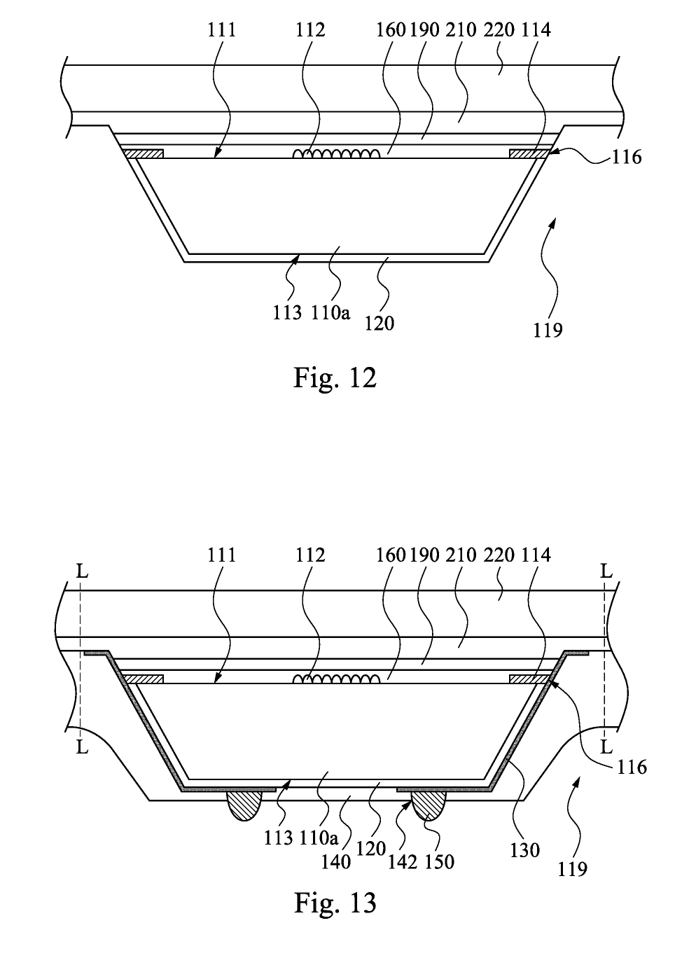

FIG. 12 is a cross-sectional view after the trench after 117 is formed in the wafer 110a of FIG. 11, after the trench 117 is covered by the isolation layer 120, and after the recess 119 is formed in the isolation layer 120, the supporting layer 190, and the temporary bonding layer 210 of FIG. 11. The difference between this embodiment and the embodiment shown in FIG. 8 is that the supporting layer 190 is located between the temporary bonding layer 210 and the wafer 110a, as illustrated in FIG. 12, and thus portions of the supporting layer 190 are cut off together with portions of the isolation layer 120 and the temporary bonding layer 210 when the formation of the recess 119.

FIG. 13 is a cross-sectional view after the redistribution layer 130 is formed on the isolation layer 120, the conductive pad 114, the supporting layer 190, and the temporary bonding layer 210 of FIG. 12, after the passivation layer 140 is formed on the isolation layer 120 shown in FIG. 12 and the redistribution layer 130, and after the conductive structure 150 is formed on the redistribution layer 130. The difference between this embodiment and the embodiment shown in FIG. 10 is that the supporting layer 190 is located between the temporary bonding layer 210 and the wafer 110a, as illustrated in FIG. 13, and thus the redistribution layer 130 at least partially protrudes from the supporting layer 190 besides protruding the conductive pad 114 when the formation of the redistribution layer 130.

After the formation of the conductive structure 150, the passivation layer 140, the temporary bonding layer 210, and the carrier 220 in the recess 119 may be cut along line L-L to form more than one chip 110 (see FIG. 3). After the cutting process, the temporary bonding layer 210 and the carrier 220 may be removed. As a result, the redistribution layer 130 protruding the passivation layer 140 and the supporting layer 190 may be exposed at the upper outside of the conductive pad 114, thereby forming the chip package 100b of FIG. 3. As shown in FIG. 3, in the subsequent manufacturing processes, the adhesive layer 170 may be formed to cover the supporting layer 190 and the redistribution layer 130 that protrudes from the supporting layer 190, and then the protection sheet 180 is adhered to the adhesive layer 170 to form the chip package 100c of FIG. 4.

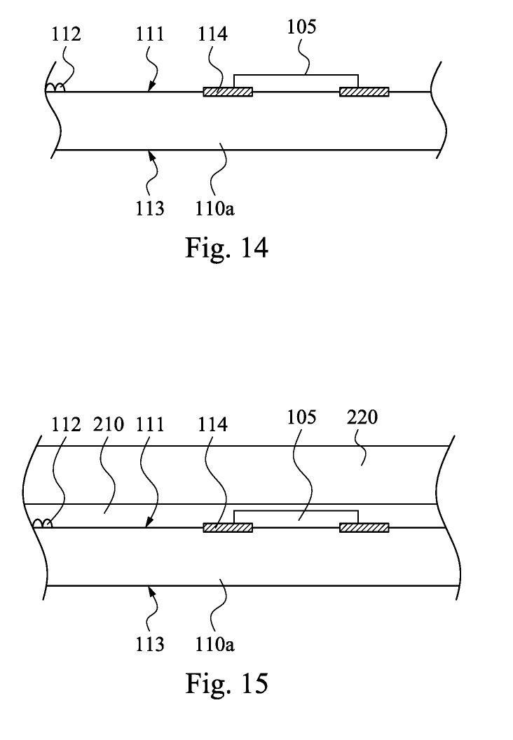

FIGS. 14 to 17 are cross-sectional views showing a manufacturing method of a chip package according to one embodiment of the present invention. As shown in FIG. 14, the wafer 110a has the sensor 112, the conductive pad 114, the top surface 111, and the bottom surface 113 that is opposite the top surface 111. The sensor 112 and the conductive pad 114 are located on the top surface 111. A dam layer 105 is formed on the top surface 111 and a first portion of the conductive pad 114 of the wafer 110a, and a second portion of the conductive pad 114 is not covered by the dam layer 105.

As shown in FIG. 15, then, the temporary bonding layer 210 is utilized to bond the carrier 220 to the wafer 110a, such that the sensor 112 and the second portion of the conductive pad 114 are covered by the temporary bonding layer 210, and the dam layer 105 is located between the temporary bonding layer 210 and the wafer 110a.

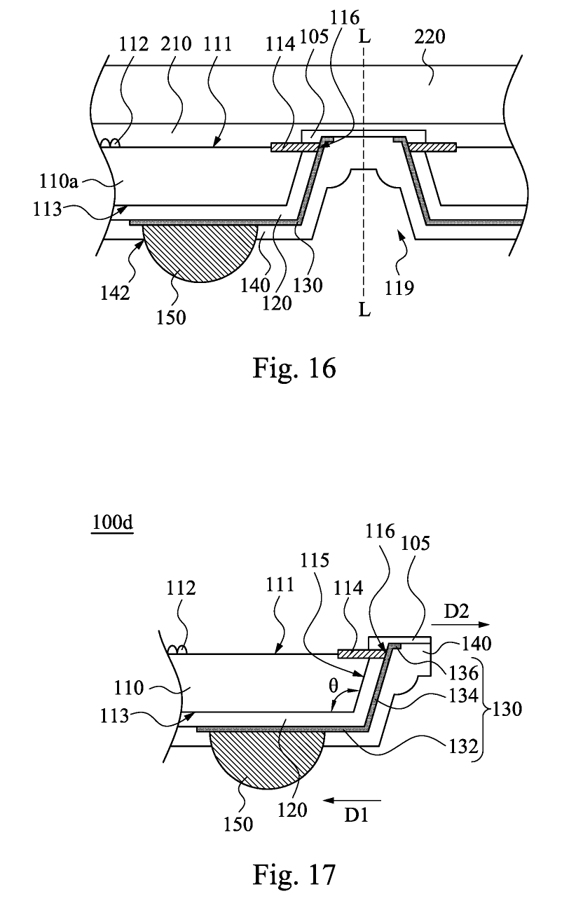

As shown in FIG. 16, after the structure of FIG. 15 is formed, the step shown in FIG. 7 may be performed. For example, the bottom surface 113 of the wafer 110a is etched to form the trench 117 (see FIG. 7) to expose the conductive pad 114, and the isolation layer 120 is formed to cover the bottom surface 113 and the trench 117 of the wafer 110a. Thereafter, the recess 119 is formed in the isolation layer 120 and the dam layer 105 that are in the trench 117, such that the side surface 116 of the conductive pad 114 is exposed through the recess 119. Afterwards, the redistribution layer 130 is formed on the isolation layer 120, the side surface 116 of the conductive pad 114, and the dam layer 105 that is in the recess 119, such that the redistribution layer 130 at least partially upwardly protrudes from the conductive pad 114. Next, the passivation layer 140 is formed on the isolation layer 120 and the redistribution layer 130, such that the redistribution layer 130 not protruding from the conductive pad 114 is located between the passivation layer 140 and the isolation layer 120, and the redistribution layer 130 protruding from the conductive pad 114 is located between the passivation layer 140 and the dam layer 105.

Thereafter, the passivation layer 140 is patterned to form at least one opening 142, and the redistribution layer 130 is exposed through the opening 142. The conductive structure 150 is formed on the redistribution layer 130 that is in the opening 142, such that the conductive structure 150 may be electrically connected to the conductive pad 114 through the redistribution layer 130. After the formation of the conductive structure 150, the passivation layer 140, the dam layer 105, the temporary bonding layer 210, and the carrier 220 in the recess 119 may be cut along line L-L, and thus the wafer 110a is diced to form more than one chip 110 (see FIG. 17).

After the cutting process, the temporary bonding layer 210 and the carrier 220 may be removed. For example, the adhesion of the temporary bonding layer 210 can be eliminated by ultraviolet. After the removal of the temporary bonding layer 210 and the carrier 220, the second portion of the conductive pad 114 and the dam layer 105 may be exposed, thereby forming the chip package 100d of FIG. 17.

The difference between the chip package 100d of FIG. 17 and the embodiment shown in FIG. 1 is that the chip package 100d further includes the dam layer 105 but has no isolation layer 160 on the top surface 111. The dam layer 105 is located on at least one portion of the conductive pad 114, at least one portion of the passivation layer 140, and the redistribution layer 130 that protrudes from the conductive pad 114. In other words, the dam layer 105 covers the first portion of the conductive pad 114, the third segment 136 of the redistribution layer 130, and the passivation layer 140 that is adjacent to the conductive pad 114.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A chip package, comprising:
a chip having a sensor, at least one conductive pad, a top surface, a bottom surface that is opposite the top surface, and a sidewall adjacent to the top surface and the bottom surface, wherein the sensor is located on the top surface, and the conductive pad is located on an edge of the top surface;
a first isolation layer located on the bottom surface and the sidewall of the chip;
a redistribution layer located on the first isolation layer, and is in electrical contact with a side surface of the conductive pad, wherein the redistribution layer at least partially protrudes from the conductive pad so as to be exposed; and
a passivation layer located on the first isolation layer and the redistribution layer, wherein the redistribution layer not protruding from the conductive pad is located between the passivation layer and the first isolation layer, and the redistribution layer protruding from the conductive pad is located on the passivation layer.

2. The chip package of claim 1, wherein an orthogonal projection of the redistribution layer that protrudes from the conductive pad on the passivation layer is not overlapped with an orthogonal projection of the chip on the passivation layer.

3. The chip package of claim 1, wherein an orthogonal projection of the redistribution layer that protrudes from the conductive pad on the passivation layer is not overlapped with an orthogonal projection of the conductive pad on the passivation layer.

4. The chip package of claim 1, wherein the redistribution layer has a first segment, a second segment, and a third segment that are connected in sequence, and the first segment is located on the first isolation layer that is on the bottom surface, and the second segment is located on the first isolation layer that is on the sidewall, and the third segment protrudes from the conductive pad and is located on the passivation layer.

5. The chip package of claim 4, wherein the first segment and the third segment of the redistribution layer extend in two opposite directions, such that the redistribution layer has a stepped shape.

6. The chip package of claim 4, wherein an obtuse angle is formed between the sidewall and the bottom surface of the chip, and another obtuse angle is formed between the first segment and the second segment of the redistribution layer.

7. The chip package of claim 1, further comprising:
a second isolation layer located on the top surface of the chip, wherein the redistribution layer at least partially protrudes from the second isolation layer so as to be exposed.

8. The chip package of claim 7, further comprising:
an adhesive layer covering the second isolation layer and the redistribution layer that protrudes from the second isolation layer; and
a protection sheet located on the adhesive layer.

9. The chip package of claim 7, further comprising:
a supporting layer located on the second isolation layer, wherein the second isolation layer is located between the supporting layer and the chip.

10. The chip package of claim 9, wherein the redistribution layer at least partially protrudes from the supporting layer so as to be exposed.

11. The chip package of claim 10, further comprising:
an adhesive layer covering the supporting layer and the redistribution layer that protrudes from the supporting layer; and
a protection sheet located on the adhesive layer.

12. The chip package of claim 9, wherein a thickness of the supporting layer is in a range from 5 μm to 15 μm.

13. The chip package of claim 9, wherein the supporting layer is made of a material comprising barium titanium oxide, silicon dioxide, or titanium dioxide.

14. The chip package of claim 1, further comprising:
a dam layer located on at least one portion of the conductive pad, at least one portion of the passivation layer, and the redistribution layer that protrudes from the conductive pad.

15. A manufacturing method of a chip package, the manufacturing method comprising:
bonding a carrier to a wafer by a temporary bonding layer, wherein the wafer has a sensor, at least one conductive pad, a top surface, and a bottom surface that is opposite the top surface, wherein the sensor and the conductive pad are located on the top surface and are covered by the temporary bonding layer;
etching the bottom surface of the wafer to form a trench to expose the conductive pad;
forming an isolation layer to cover the bottom surface and the trench of the wafer;
forming a recess in the isolation layer and the temporary bonding layer that are in the trench, thereby exposing a side surface of the conductive pad through the recess;
forming a redistribution layer on the isolation layer, the side surface of the conductive pad, and the temporary bonding layer that is in the recess, wherein the redistribution layer at least partially protrudes from the conductive pad; and
removing the temporary bonding layer and the carrier to expose the redistribution layer that protrudes from the conductive pad.

16. The manufacturing method of claim 15, further comprising:
forming a passivation layer on the isolation layer and the redistribution layer, wherein the redistribution layer not protruding from the conductive pad is located between the passivation layer and the isolation layer, and the redistribution layer protruding from the conductive pad is located on the passivation layer.

17. The manufacturing method of claim 16, further comprising:
patterning the passivation layer to form at least one opening, wherein the redistribution layer is exposed through the opening; and
forming a conductive structure on the redistribution layer that is in the opening.

18. The manufacturing method of claim 16, further comprising:
cutting the passivation layer, the temporary bonding layer, and the carrier that are in the recess.

19. The manufacturing method of claim 15, wherein bonding the carrier to the wafer by the temporary bonding layer further comprising:
forming a supporting layer on the top surface of the wafer, thereby bonding the carrier to the supporting layer.

20. The manufacturing method of claim 19, wherein the redistribution layer at least partially protrudes from the supporting layer, and the manufacturing method further comprises:
forming an adhesive layer to cover the supporting layer and the redistribution layer that protrudes from the supporting layer; and
adhering a protection sheet to the adhesive layer.

21. The manufacturing method of claim 15, further comprising:
forming an adhesive layer to cover the top surface of the wafer and the redistribution layer that protrudes from the conductive pad; and
adhering a protection sheet to the adhesive layer.

22. A manufacturing method of a chip package, comprising:
forming a dam layer on a top surface of a wafer and a first portion of a conductive pad of the wafer, wherein the wafer has a sensor and a bottom surface that is opposite the top surface, and the sensor and the conductive pad are located on the top surface;
adhering a carrier to the wafer by a temporary bonding layer, wherein the sensor and a second portion of the conductive pad are covered by the temporary bonding layer, and the dam layer is located between the temporary bonding layer and the wafer;
etching the bottom surface of the wafer to form a trench to expose the conductive pad;
forming an isolation layer to cover the surface and the trench of the wafer;
forming a recess in the isolation layer and the dam layer that are in the trench, thereby exposing a side surface of the conductive pad through the recess;
forming a redistribution layer on the isolation layer, the side surface of the conductive pad, and the dam layer that is in the recess, wherein the redistribution layer at least partially protrudes from the conductive pad; and
removing the temporary bonding layer and the carrier to expose the second portion of the conductive pad and the dam layer.

23. The manufacturing method of claim 22, further comprising:
forming a passivation layer on the isolation layer and the redistribution layer, wherein the redistribution layer not protruding from the conductive pad is located between the passivation layer and the isolation layer, and the redistribution layer protruding from the conductive pad is located between the passivation layer and the dam layer.

24. The manufacturing method of claim 23, further comprising:
patterning the passivation layer to form at least one opening, wherein the redistribution layer is exposed through the opening; and
forming a conductive structure on the redistribution layer that is in the opening.

25. The manufacturing method of claim 23, further comprising:
cutting the passivation layer, the dam layer, the temporary bonding layer, and the carrier in the recess.
